(19) United States
(12) Patent Application Publication
(10) Pub. No.: US 2014/0061461 A1
(43) Pub. Date: Mar. 6, 2014

(54) DEFECT INSPECTION APPARATUS, DEFECT INSPECTION METHOD AND NON-TRANSITORY COMPUTER READABLE RECORDING MEDIUM

(71) Applicants: Hiroyuki HAYASHI, Yokkaichi-Shi (JP); Yuichiro Yamazaki, Yokkaichi-Shi (JP)

(72) Inventors: Hiroyuki HAYASHI, Yokkaichi-Shi (JP); Yuichiro Yamazaki, Yokkaichi-Shi (JP)

(21) Appl. No.: 13/713,519

(22) Filed: Dec. 13, 2012

Related U.S. Application Data
(60) Provisional application No. 61/694,424, filed on Aug. 29, 2012.

(51) Int. Cl. H01J 37/26

(52) U.S. Cl. CPC H01J 37/263
USPC 250/307; 250/310

(57) ABSTRACT

In accordance with an embodiment, a defect inspection apparatus includes an electron beam applying unit, a detection unit, a signal processing unit, and a control unit. The electron beam applying unit applies an electron beam to a semiconductor substrate on which first to N-th (N is a natural number equal to or more than 2) patterns are periodically provided. The patterns are respectively made of first to N-th materials in descending order of the emission amount of secondary electrons or reflected electrons. The detection unit detects the secondary electrons or reflected electrons from the patterns to output a signal. The signal processing unit processes the signal to form a potential contrast image of the patterns. The control unit acquires a potential contrast signal waveform including N signal waveforms respectively corresponding to the N patterns, analyzes the potential contrast signal waveform to acquire positional information to scan the desired pattern.

### CROSS REFERENCE TO RELATED APPLICATIONS

This application is based upon and claims the benefit of priority from the prior provisional Application 61/694,424 filed on Aug. 29, 2012 in USA, the entire contents of which are incorporated herein by reference.

### FIELD

Embodiments described herein relate generally to a defect inspection apparatus, a defect inspection method and a non-transitory computer readable recording medium.

### BACKGROUND

A defect inspection method is used in a defect inspection in the process of manufacturing a semiconductor device, in which an electron beam is applied to the surface of a semiconductor substrate, and an image (hereinafter referred to as a “potential contrast image”) having contrast corresponding to a potential distribution in the surfaces of wiring lines included in one particular chip in the surface of the semiconductor substrate is acquired, the potential contrast images of the surface of the same wiring line are then compared with each other regarding adjacent cells or adjacent dies to detect a defect in the wiring line, for example, a defect resulting from an electric failure in a boring process. Such a defect inspection method is generally called a cell-to-cell image comparison inspection method or a die-to-die image comparison inspection method, and is in wide use.

The cell-to-cell image comparison inspection method is used to inspect a die having repeated wiring lines as in a memory device. The die-to-die image comparison inspection method is used to inspect a die having no repeated wiring lines as in a logic device.

In connection with the inspection method to detect a critical defect (breaking and short circuit of a wiring line) present in a lower layer of the wiring line from a difference image of the potential contrast images of the wiring line surface, attention is drawn to the improvement of the efficiency of a defect detection by only scanning an inspection target wiring line such as a contact wiring line with an electron beam to increase the speed of inspection. This speed increasing technique increases the speed by not scanning patterns which are not targeted for inspection with an electron beam.

However, according to the speed increasing technique, in the defect inspection of a pattern including different materials, for example, a pattern in which a contact wiring line, an oxide film, and a metal wiring line are periodically arranged on a semiconductor substrate, a signal from the wiring line which is not targeted for inspection, for example, the metal wiring line becomes noise, and the inspection speed may be rather decreased.

### BRIEF DESCRIPTION OF THE DRAWINGS

In the accompanying drawings:

FIG. 1 is a block diagram showing a general structure of a defect inspection apparatus according to an embodiment;

FIG. 2 is a diagram showing an example of a potential contrast image;

FIG. 3 is a flowchart showing a general procedure of a defect inspection method according to the embodiment;

FIG. 4 is a graph showing a potential contrast signal waveform obtained from the potential contrast image shown in FIG. 2;

FIG. 5 is a graph showing a signal waveform of a metal wiring line pattern filtered out from the potential contrast signal waveform shown in FIG. 4;

FIG. 6 is a graph showing a potential contrast signal waveform after the filtering; and

FIG. 7 is a graph illustrating a filtering method when there is included a pattern which is smaller in the emission amount of secondary electrons or reflected electrons than a desired pattern but the emission amount is at a considerable level.

### DETAILED DESCRIPTION

In accordance with an embodiment, a defect inspection apparatus includes an electron beam applying unit, a detection unit, a signal processing unit, and a control unit. The electron beam applying unit applies an electron beam to a semiconductor substrate on which first to N-th (N is a natural number equal to or more than 2) patterns are periodically provided. The first to N-th patterns are respectively made of first to N-th materials in descending order of the emission amount of secondary electrons or reflected electrons. The detection unit detects the secondary electrons or reflected electrons generated from the patterns and outputs a signal. The signal processing unit processes the signal to form a potential contrast image of the patterns. The control unit acquires, from the potential contrast image, a first potential contrast signal waveform including N signal waveforms respectively corresponding to the N patterns, analyzes the first potential contrast signal waveform, extracts a signal waveform of a desired pattern among the second to N-th patterns to acquire positional information used to scan the desired pattern with the electron beam, and controls the electron beam applying unit in such a manner that the electron beam is applied to the desired pattern in accordance with the positional information.

Embodiments will now be explained with reference to the accompanying drawings. Like components are provided with like reference signs throughout the drawings and repeated descriptions thereof are appropriately omitted.

(1) Defect Inspection Apparatus

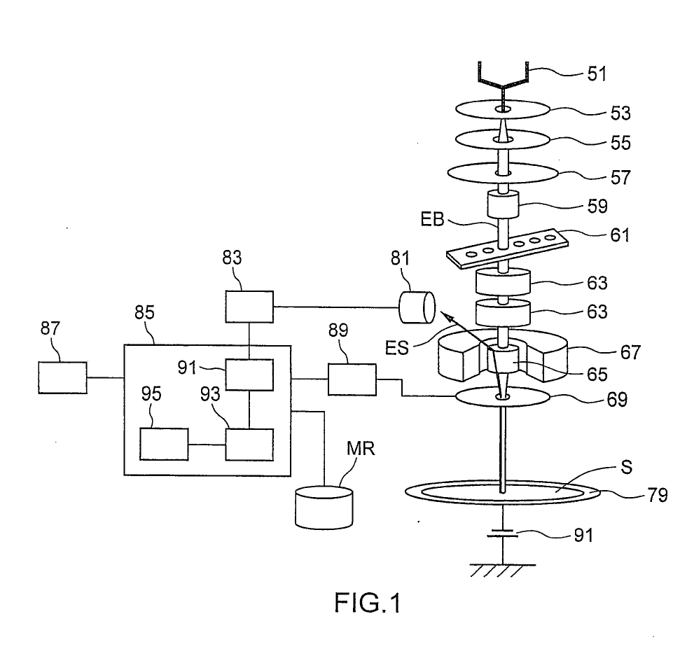

FIG. 1 is a block diagram showing a general structure of a defect inspection apparatus according to the embodiment. The defect inspection apparatus shown in FIG. 1 includes an electron gun 51, a suppressor electrode 53, an extraction electrode 55, a condenser lens 57, a Wien filter (top) 59, an aperture 61, a beam scan deflector 63, a Wien filter (bottom) 65, an objective lens 67, a charge control electrode 69, a substrate stage 79, a detection unit 81, a signal processing unit 83, a control computer 85, a memory MR, a display device 87, and a direct-current power supply 89.

The electron gun 51 generates an electron beam, and applies the electron beam to a semiconductor substrate S as a primary electron beam EB. The suppressor electrode 53, the extraction electrode 55, the condenser lens 57, the Wien filters 59 and 65, the aperture 61, the beam scan deflector 63, the objective lens 67, and the charge control electrode 69 constitute an electron optical system, and controls the size, track, and focal position of a beam flux of the primary electron beam EB. In the present embodiment, the electron gun 51 and the electron optical system correspond to, for example, an electron beam applying unit.

The control computer 85 reads a file in association with an inspection target from a recipe file stored in the memory MR, and controls the electron gun 51 and the electron optical system via unshown various controllers to conduct a defect inspection. The direct-current power supply 89 applies a direct-current voltage (positive and negative) to the charge control electrode 69, and extracts, from the surface of the semiconductor substrate S, secondary electrons or reflected electrons obtained from the surface of the semiconductor substrate S, and pushes back the secondary electrons or reflected electrons to the semiconductor substrate S. The direct-current power supply 89 thereby controls the charging state (positive charging or negative charging) of the surface of the semiconductor substrate S.

The substrate stage 79 supports the semiconductor substrate S.

The primary electron beam EB emitted from the electron gun 51 is condensed by the suppressor electrode 53, the extraction electrode 55, and the condenser lens 57, and enters the Wien filter 59. The Wien filter 59 allows the incident primary electron beam EB to travel straight without being deflected and enter the objective lens 67. The objective lens 67 condenses the primary electron beam EB in such a manner that the primary electron beam EB is formed into an image on the surface of the substrate S. The condensed primary electron beam EB is deflected by the beam scan deflector 63 and the semiconductor substrate S is thus scanned with the primary electron beam EB.

As a result of the scanning with the primary electron beam EB, secondary electrons or reflected electrons ES are emitted from the surfaces of wiring lines formed on the semiconductor substrate S. The secondary electrons or reflected electrons ES are accelerated by an electric field formed between the semiconductor substrate S and the objective lens 67, and then enter the Wien filter 65. The secondary electrons or reflected electrons ES are deflected by the Wien filter 65, and are then drawn into the detection unit 81. The detection unit 81 outputs a signal indicating the amount of the detected secondary electrons or reflected electrons ES. The signal processing unit 83 processes the received signal to form a potential contrast image, and supplies the potential contrast image to the control computer 85.

The control computer 85 includes an analyzer 91, a filter 93, and a scan position determiner 95. The control computer 85 causes the display device 87 to display the potential contrast image received from the signal processing unit 83 on, for example, a liquid crystal display. The control computer 85 also performs predetermined processing for the potential contrast image to acquire information on the scan position of a desired wiring line pattern, and again controls the electron gun 51 and the electron optical system to only scan the desired wiring line pattern with the primary electron beam EB, thereby acquiring a potential contrast image which does not include other wiring line patterns.

Receiving the potential contrast image from the signal processing unit 83, the analyzer 91 acquires a potential contrast signal waveform, and finds a position with a maximum peak value.

The filter 93 filters out a signal waveform portion to which the maximum peak value acquired by the analyzer 91 belongs from the potential contrast signal waveform.

The scan position determiner 95 acquires, from a peak value in the potential contrast signal waveform after the filtering, positional information used to scan a desired wiring line pattern with the primary electron beam EB.

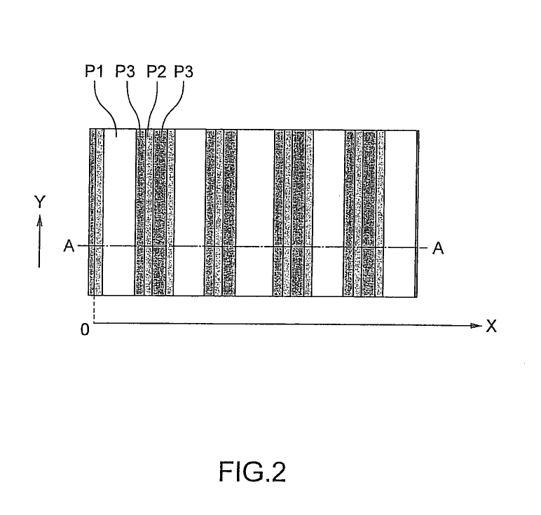

An embodiment of a defect inspection method that uses the defect inspection apparatus shown in FIG. 1 is described with reference to FIG. 2 to FIG. 7.

(2) Defect Inspection Method

FIG. 2 is a diagram showing an example of a potential contrast image. In the example shown in FIG. 2, a metal wiring line pattern P1, an oxide film pattern P3, a contact wiring line pattern P2, and an oxide film pattern P3 are adjacently formed on the semiconductor substrate S, and are periodically arranged in an X-direction. The amounts of secondary electrons or reflected electrons emitted from the patterns P1 to P3 by the application of the primary electron beam EB vary according to the materials of the patterns. The metal wiring line pattern emits the greatest amount of electrons, and the oxide film pattern emits a significantly small amount of electrons. In the present embodiment, the metal wiring line pattern P1 corresponds to, for example, a first pattern, the contact wiring line pattern P2 corresponds to, for example, a second pattern, and the oxide film pattern P3 corresponds to, for example, a third pattern.

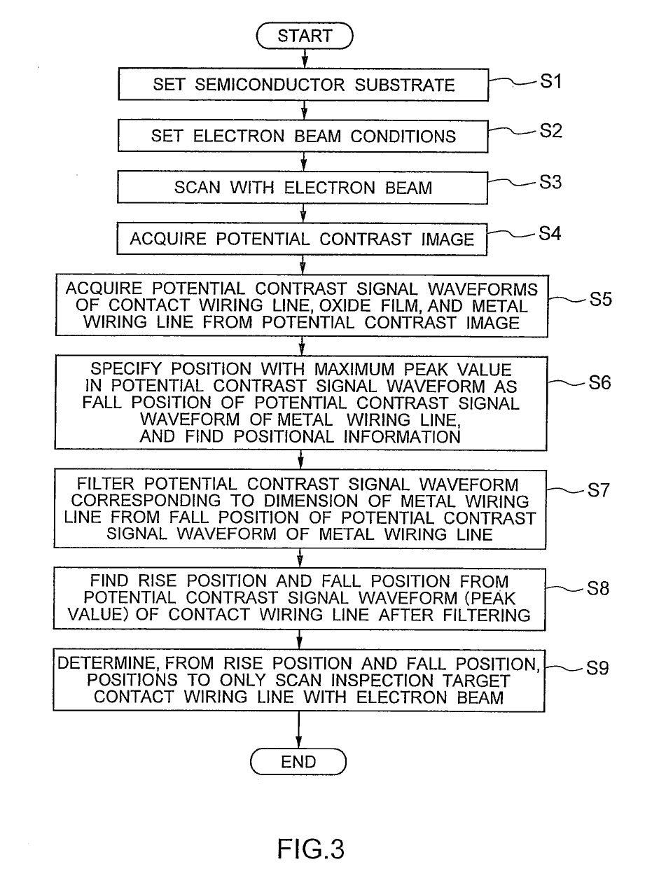

FIG. 3 is a flowchart showing a general procedure of the defect inspection method according to the embodiment.

First, the semiconductor substrate S on which an inspection target pattern is formed is set on the substrate stage 79 (step S1), and optical conditions of an electron beam is set via an unshown input device (step S2).

The electron optical system is then driven to apply the primary electron beam EB, and an inspection target region on the semiconductor substrate S is scanned (step S3). The secondary electrons or reflected electrons ES emitted from the surface of the inspection target pattern are detected by the detection unit 81, and detection signals are processed by the signal processing unit 83. Thereby, for example, the potential contrast image shown in FIG. 2 is acquired (FIG. 3, step S4).

A potential contrast signal waveform is then acquired from the potential contrast image by the analyzer 91 (step S5).

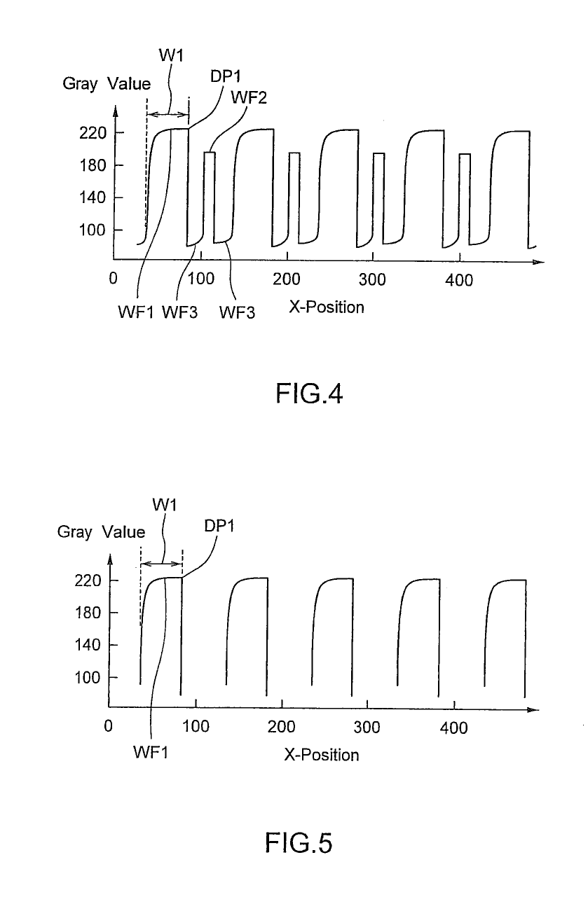

The potential contrast signal waveform acquired from the potential contrast image in FIG. 2 is shown in FIG. 4. The signal waveform in FIG. 4 is obtained by plotting the gray values of pixels along the line A-A parallel to the X-axis in FIG. 2. The signal waveform in FIG. 4 is composed of the repetition of two signal waveforms WF1, WF3, WF2, and WF3. The signal waveforms WF1, WF2, and WF3 correspond to the metal wiring line pattern P1, the contact wiring line pattern P2, and the oxide film pattern P3, respectively. In the present embodiment, the potential contrast signal waveform shown in FIG. 4 corresponds to, for example, a first potential contrast signal waveform.

The analyzer 91 then searches for a position with a maximum peak value in the whole potential contrast signal waveform, and specifies the position that has been searched for as a fall position of the signal waveform WF1 of the metal wiring line pattern P1. The analyzer 91 obtains information on this position, and supplies the information to the filter 93 (FIG. 3, step S6). In accordance with the signal waveform in FIG. 4, a position indicated by a sign DP1 has the maximum peak value, and this position can be specified as the fall position of the signal waveform WF1.

Tracking back to the origin in the X-direction from the fall position of the signal waveform WF1 by the amount corresponding to the dimension of the metal wiring line pattern P1, the filter 93 filters out the potential contrast waveform (step S7).

FIG. 5 shows the signal waveform WF1 to be removed from the signal waveform in FIG. 4. The waveform in a region specified by tracking back toward the origin from the fall position DP1 by a predetermined width W1 is targeted for filtering. A design value of the width of the metal wiring line pattern P1 can be used as the value of the predetermined width W1. This design value is previously stored in the memory device MR in the present embodiment, and is loaded from the memory device MR by the filter 93 to perform the filtering processing. In the present embodiment, the predetermined width W1 shown in FIG. 4 and FIG. 5 corresponds to, for example, a first reference width. The dimension to be tracked back toward the origin in the X-direction from the fall position DP1 is not limited to the design value of the width of the metal wiring line pattern P1, and may be a value obtained by multiplying the design value by a correction value according to process variations or may be an actually measured value of the width of the metal wiring line pattern P1.

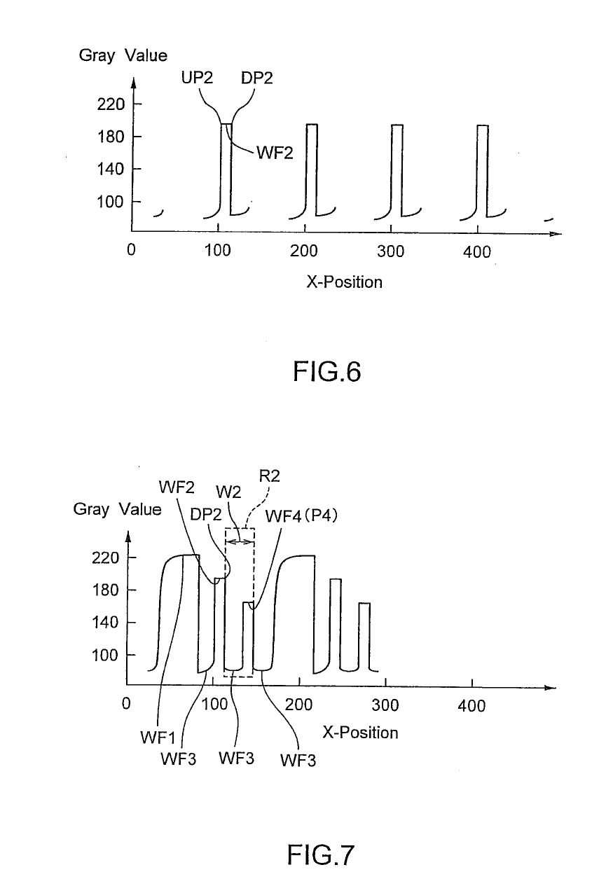

An example of the potential contrast signal waveform after the filtering by the filter 93 is shown in FIG. 6. As the signal waveform in FIG. 5 has been removed from the signal waveform in FIG. 4, the signal waveform shown in FIG. 6 is composed of the signal waveform WF2 of the contact wiring line pattern P2 and a part of the signal waveform WF3 of the oxide film pattern P3. The potential contrast signal waveform after the filtering is supplied to the scan position determiner 95. In the present embodiment, the potential contrast signal waveform shown in FIG. 6 corresponds to, for example, a second potential contrast signal waveform.

The scan position determiner 95 further searches for a peak position in the potential contrast signal waveform after the filtering, and specifies the rise position and fall position of the signal waveform WF2 of the contact wiring line pattern P2 (FIG. 3; step S8). In the example shown in FIG. 5, positions indicated by signs UP2 and DP2 are searched for as peak positions, and specified as the rise position UP2 and fall position DP2 of the signal waveform WF2, respectively.

From the specified rise position and fall position, the scan position determiner 95 further determines positions only to scan, with the electron beam EB, an inspection target wiring line pattern, in the present embodiment, the contact wiring line pattern P2 (step S9).

Finally, in accordance with the determined position, the control computer 85 again controls the electron gun 51 and the electron optical system only to scan the desired contact wiring line pattern P2 with the primary electron beam EB, thereby acquiring a potential contrast image which does not include the other wiring line patterns P1 and P3.

In the embodiment described above, as the pattern having a lower peak value of the signal waveform than the desired contact wiring line pattern P2 is the oxide film pattern P3 alone, the positional information used to scan the contact wiring line pattern P2 can be acquired by only filtering out the signal waveform of the metal wiring line pattern having the maximum peak value. However, when there is not only a pattern made of a material with a significantly small emission amount of secondary electrons or reflected electrons such as an oxide film but there is also a pattern with an emission amount which is smaller than that of a desired pattern but which is at a considerable level, the corresponding signal waveform also needs to be filtered out.

FIG. 7 shows an example of the potential contrast signal waveform when such a pattern is included. In the example shown in FIG. 7, a pattern P4 is located between the contact wiring line pattern P2 and the metal pattern P1 so as to be sandwiched by the oxide film patterns P3. The difference in the emission amount of secondary electrons or reflected electrons between the pattern P4 and the contact wiring line pattern P2 is substantially equal to the difference between the metal wiring line pattern P1 and the contact wiring line pattern P2.

In this case, data on the width of the oxide film pattern P3 and the width of the pattern P4 are previously stored in the memory device MR, the filter 93 has only to extract the data from the recording device MR to find a sum value W2, specify a region R2 extending from the fall position DP2 of the contact wiring line pattern P2 to the right of the drawing of FIG. 7 by the width of the sum value W2, and filter out the region R2. Design values can be used as the data on the width of the oxide film pattern P3 and the width of the pattern P4. As in the case of the predetermined width W1 shown in FIG. 4 and FIG. 5, the data may be a value obtained by multiplying the design value by a correction value according to process variations or may be actually measured values of the oxide film pattern P3 and the pattern P4. In the present embodiment, the sum value W2 corresponds to, for example, a second reference width.

According to the above-described at least one embodiment, the potential contrast signal waveform is filtered out by tracking back from the fall position of the potential contrast signal waveform of the metal wiring line pattern P1 to be a noise source by the width of the wiring line of the contact wiring line pattern P. Therefore, the effect of the noise is removed, and the potential contrast image of the inspection target contact wiring line pattern P2 alone can be accurately acquired. Consequently, it is possible to provide a defect inspection apparatus and a defect inspection method that can increase the speed of inspection.

(3) Program and Non-Transitory Recording Medium

A series of procedures of the defect inspection method described above may be incorporated in a program, and read into and executed by a control computer of the defect inspection apparatus. This enables the defect inspection described above to be carried out by use of a general-purpose defect inspection apparatus. A series of procedures of the defect inspection described above may be stored in a non-transitory recording medium such as a flexible disk or a CD-ROM as a program to be executed by the control computer of the defect inspection apparatus, and read into and executed by the control computer.

The non-transitory recording medium is not limited to a portable medium such as a magnetic disk or an optical disk, and may be a fixed recording medium such as a hard disk drive or a memory. The program incorporating the series of procedures of the defect inspection described above may be distributed via a communication line (including wireless communication) such as the Internet. Moreover, the program incorporating the series of procedures of the defect inspection described above may be distributed in an encrypted, modulated or compressed state via a wired line or a wireless line such as the Internet or in a manner stored in a recording medium.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A defect inspection apparatus comprising:
an electron beam applying unit configured to apply an electron beam to a semiconductor substrate on which first to N-th (N is a natural number equal to or more than 2) patterns are periodically provided, the first to N-th patterns being respectively made of first to N-th materials in descending order of the emission amount of secondary electrons or reflected electrons;
a detection unit configured to detect the secondary electrons or reflected electrons generated from the patterns and configured to output a signal;
a signal processing unit configured to process the signal to form a potential contrast image of the patterns;
a control unit configured to acquire, from the potential contrast image, a first potential contrast signal waveform which comprises N signal waveforms respectively corresponding to the N patterns, to analyze the first potential contrast signal waveform, to extract a signal waveform of a desired pattern among the second to N-th patterns to acquire positional information used to scan the desired pattern with the electron beam, and to control the electron beam applying unit in such a manner that the electron beam is applied to the desired pattern in accordance with the positional information.

2. The apparatus of claim 1,
wherein the control unit comprises:
an analyzer configured to define a position with a maximum peak value in the first potential contrast signal waveform as a fall position of a waveform of the first pattern to find its positional information, and
a filter configured to filter the first potential contrast signal waveform from the fall position by a first reference width corresponding to the width of the first pattern.

3. The apparatus of claim 2,
wherein the desired pattern is the second pattern, and
the control unit further comprises a scan position determiner configured to acquire the positional information of the second pattern from a peak value in a second potential contrast signal waveform after the filtering.

4. The apparatus of claim 3,
wherein the scan position determiner specifies a rise position and a fall position of the signal waveform of the second pattern, and acquires the positional information from the specified rise position and fall position.

5. The apparatus of claim 4,
wherein the filter further filters the second potential contrast signal waveform from the specified fall position of the signal waveform of the second pattern by a second reference width corresponding to a width extending from the third pattern to the N-th pattern.

6. A defect inspection method comprising:
applying an electron beam to a semiconductor substrate on which first to N-th (N is a natural number equal to or more than 2) patterns are periodically provided, the first to N-th patterns being respectively made of first to N-th materials in descending order of the emission amount of secondary electrons or reflected electrons;
detecting the secondary electrons or reflected electrons generated from the patterns and outputting a signal;
processing the signal to form a potential contrast image of the patterns;
acquiring, from the potential contrast image, a first potential contrast signal waveform which comprises N signal waveforms respectively corresponding to the N patterns, and
analyzing the first potential contrast signal waveform, extracting a signal waveform of a desired pattern among the second to N-th patterns to acquire positional information used to scan the desired pattern with the electron beam.

7. The method of claim 6,
wherein extracting a signal waveform of a desired pattern comprises defining a position with a maximum peak value in the first potential contrast signal waveform as a fall position of a waveform of the first pattern to find its positional information, and filtering the first potential contrast signal waveform from the fall position by a first reference width corresponding to the width of the first pattern.

8. The method of claim 7,
wherein the first reference width is determined by use of a design value of the first pattern.

9. The method of claim 7,
wherein the desired pattern is the second pattern,
the positional information of the second pattern is acquired from a peak value in a second potential contrast signal waveform after the filtering.

10. The method of claim 8, further comprising specifying a rise position and a fall position of the signal waveform of the second pattern from a peak value in a second potential contrast signal waveform,
wherein the positional information is acquired from the specified rise position and fall position.

11. The method of claim 10, further comprising filtering the second potential contrast signal waveform from the specified fall position of the signal waveform of the second pattern by a second reference width corresponding to a width extending from the third pattern to the Nth pattern.

12. The method of claim 11,
wherein the second reference width is determined by use of design values of the third to N-th patterns.

13. A non-transitory computer-readable recording medium containing a program which causes a computer configured to control a defect inspection apparatus to execute a defect inspection, the defect inspection apparatus comprising an electron beam applying unit configured to apply an electron beam to a sample, a detection unit configured to detect secondary electrons or reflected electrons generated from the sample by the application of the electron beam and configured to output a signal, and a signal processing unit configured to process the signal to form a potential contrast image of patterns, the defect inspection comprising:
applying an electron beam to a semiconductor substrate on which first to N-th (N is a natural number equal to or more than 2) patterns are periodically provided, the first to N-th patterns being respectively made of first to N-th materials in descending order of the emission amount of secondary electrons or reflected electrons;
detecting the secondary electrons or reflected electrons generated from the patterns and outputting a signal;
processing the signal to form a potential contrast image of the patterns;
acquiring, from the potential contrast image, a first potential contrast signal waveform which comprises N signal waveforms respectively corresponding to the N patterns, and
analyzing the first potential contrast signal waveform, extracting a signal waveform of a desired pattern among the second to N-th patterns to acquire positional information used to scan the desired pattern with the electron beam.
